(19) United States
(12) Patent Application Publication
(10) Pub. No.: US 2026/0190217 A1
(43) Pub. Date: Jul. 2, 2026

(54) STRETCHABLE DISPLAY DEVICE

(71) Applicant: AUO Corporation, Hsinchu City (TW)

(72) Inventors: Yi-Ting Yeh, Hsinchu City (TW); Kent-Yi Lee, Hsinchu City (TW); Ju-Wen Chang, Hsinchu City (TW); Yu-Sheng Huang, Hsinchu City (TW)

(73) Assignee: AUO Corporation, Hsinchu City (TW)

(21) Appl. No.: 19/234,307

(22) Filed: Jun. 11, 2025

(30) Foreign Application Priority Data
Dec. 31, 2024 (TW) 113151734

(51) Int. Cl. H05K 1/02; G06F 1/16

(52) U.S. Cl. CPC H05K 1/0283; G06F 1/1652

(57) ABSTRACT

A stretchable circuit substrate including a plurality of island structures, a first organic layer and a first conductive layer is provided. The island structures are respectively disposed on a plurality of active regions. The island structures include a first island structure and a second island structure, and each island structure includes a driving structure. The first organic layer is at least disposed on a circuit region between the first island structure and the second island structure, and connected to the first island structure and the second island structure. The first conductive layer is disposed on the first organic layer, and electrically connected to the driving structure of the first island structure and the driving structure of the second island structure.

### CROSS-REFERENCE TO RELATED APPLICATION

This application claims the priority benefit of Taiwan application serial no. 113151734, filed on Dec. 31, 2024. The entirety of the above-mentioned patent application is hereby incorporated by reference herein and made a part of this specification.

### BACKGROUND

### Technical Field

The disclosure relates to a stretchable display device, and in particular relates to a stretchable circuit substrate.

### Description of Related Art

In recent years, stretchable, thin, and form-factor-unrestricted electronic products have gradually gained prominence. The stretchable circuit substrates inside these electronic products usually have inorganic layers disposed on the active region and the circuit region. However, inorganic layers are susceptible to fracture when stretched, consequently leading to circuit substrate disconnection. Therefore, enhancing the reliability of stretchable circuit substrates has become an urgent issue requiring resolution.

### SUMMARY

A stretchable circuit substrate with high maximum stretchability ratio and good reliability is provided in the disclosure.

According to an embodiment of the disclosure, a stretchable circuit substrate is provided, which has multiple active regions and multiple circuit regions. The circuit regions are respectively located between the active regions. The stretchable circuit substrate includes multiple island structures, a first organic layer and a first conductive layer. The island structures are respectively disposed on the active regions. The island structures include a first island structure and a second island structure, and each of the island structures includes a driving structure. The first organic layer is at least disposed on a circuit region between the first island structure and the second island structure, and connected to the first island structure and the second island structure. The first conductive layer is disposed on the first organic layer, and electrically connected to the driving structure of the first island structure and the driving structure of the second island structure.

According to another embodiment of the disclosure, a stretchable circuit substrate is provided, which has multiple active regions and multiple circuit regions. The circuit regions are respectively located between the active regions. The stretchable circuit substrate includes multiple island structures, a first organic layer and a first conductive layer. The island structures are respectively disposed on the active regions. The island structures include a first island structure and a second island structure, and each of the island structures includes a driving structure. The first organic layer is at least disposed on a circuit region between the first island structure and the second island structure, and connected to the first island structure and the second island structure. The first conductive layer is disposed on the first organic layer, and electrically connected to the driving structure of the first island structure and the driving structure of the second island structure. The first island structure further includes at least one inorganic layer, and the first organic layer is further disposed on a top surface of the at least one inorganic layer. The first organic layer is further disposed on at least one side surface of the at least one inorganic layer. The first organic layer is further disposed on a circuit region between the first island structure and a third island structure, and the first organic layer is integrally formed.

Based on the above, the stretchable circuit substrate provided by the embodiment of the disclosure is configured with an organic layer on the circuit region between different island structures, and the corresponding island structures are connected by the organic layer, which effectively enhances the maximum stretchability ratio of the stretchable circuit substrate and prevents fractures from readily occurring at the interface between its active region and circuit region.

In order to make the above-mentioned features and advantages of the disclosure comprehensible, embodiments accompanied with drawings are described in detail below.

### BRIEF DESCRIPTION OF THE DRAWINGS

FIG. 1 is a planar schematic diagram of a stretchable circuit substrate according to some embodiments of the disclosure.

FIG. 2 is a cross-sectional schematic diagram along a curve AA′ shown in FIG. 1 according to an embodiment of the disclosure.

FIG. 3 is a cross-sectional schematic diagram along a curve AA′ shown in FIG. 1 according to an embodiment of the disclosure.

FIG. 4A to FIG. 4C are planar schematic diagrams of the first island structure in FIG. 1 and FIG. 3 according to an embodiment of the disclosure, and FIG. 4D is a cross-sectional schematic diagram along each line segment BB′ shown in FIG. 4A to FIG. 4C.

FIG. 5A to FIG. 5D are planar schematic diagrams of the first island structure in FIG. 1 and FIG. 3 according to an embodiment of the disclosure, and FIG. 5E is a cross-sectional schematic diagram along each line segment BB′ shown in FIG. 5A to FIG. 5D.

### DETAILED DESCRIPTION OF DISCLOSED EMBODIMENTS

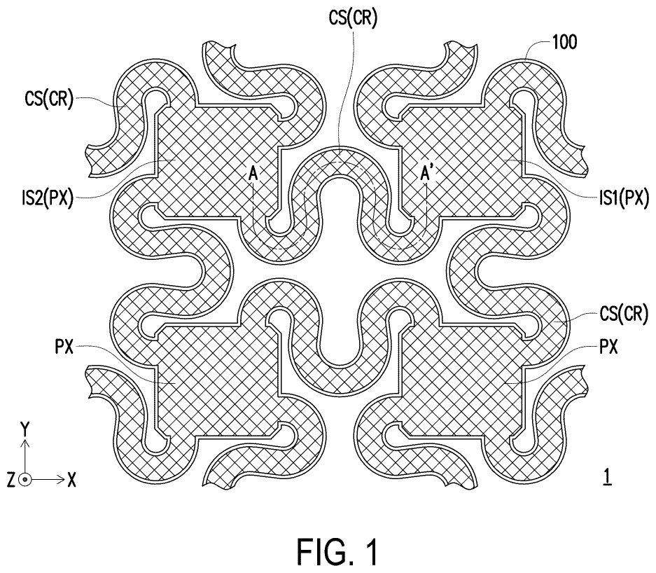

Referring to FIG. 1, FIG. 1 is a planar schematic diagram of a stretchable circuit substrate according to some embodiments of the disclosure.

The stretchable circuit substrate 1 has multiple active regions PX and multiple circuit regions CR. The circuit regions CR are respectively located between the active regions PX. The stretchable circuit substrate 1 includes multiple island structures and multiple circuit structures CS. An island structure is disposed on each active region PX, and a circuit structure CS is disposed on each circuit region CR. The island structures include a first island structure IS1 and a second island structure IS2.

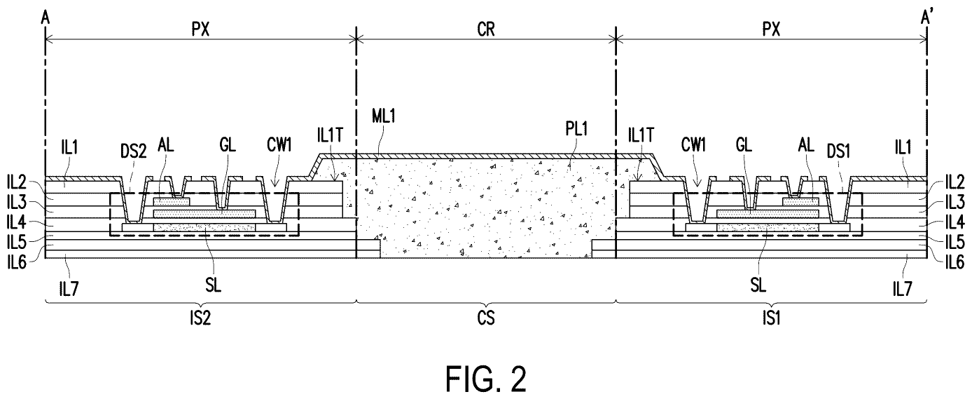

Referring to FIG. 2, FIG. 2 is a cross-sectional schematic diagram along a curve AA′ shown in FIG. 1 according to an embodiment of the disclosure.

In the first embodiment, a circuit structure CS is disposed on the circuit region CR between the first island structure IS1 and the second island structure IS2. The circuit structure CS includes a first organic layer PL1 and a first conductive layer ML1 on the first organic layer PL1. The material of the first organic layer PL1 may include polyimide (PSPI), phenol-formaldehyde resin, epoxy resin, polyisoprene rubber, or analogous materials thereof. The material of the first conductive layer ML1 may include copper, titanium, aluminum, or other conductive materials with good ductility. As shown in FIG. 2, the first organic layer PL1 on the circuit region CR is connected to the first island structure IS1 and the second island structure IS2. The first island structure IS1 includes a driving structure DS1, and the second island structure IS2 includes a driving structure DS2. The driving structure DS1 and the driving structure DS2 include thin film transistors. The first conductive layer ML1 is electrically connected to the driving structure DS1 of the first island structure IS1 and the driving structure DS2 of the second island structure IS2.

It should be noted that in a stretchable circuit substrate provided according to a comparative example, an inorganic layer is disposed on the circuit region CR between the first island structure IS1 and the second island structure IS2, and the inorganic layer is connected to the first island structure IS1 and the second island structure IS2. However, the maximum stretchability ratio of the stretchable circuit substrate provided in the comparative example is about 6%, thereby the stretchable circuit substrate is susceptible to fractures in the circuit region CR and at the interface between the active region PX and the circuit region CR. In contrast, in the stretchable circuit substrate 1 provided according to the embodiment of the disclosure, the first organic layer PL1 is disposed on the circuit region CR between the first island structure IS1 and the second island structure IS2. The maximum stretchability ratio of the stretchable circuit substrate 1 is about 27.3%, which is about 4.55 times higher than that of the comparative example. The stretchable circuit substrate 1 is not prone to fractures at the interface between the active region PX and the circuit region CR, and the first organic layer PL1 in the circuit region CR is also not prone to fractures, and has good reliability.

On the other hand, as shown in FIG. 2, the first island structure IS1 and the second island structure IS2 further include inorganic layers IL1, IL2, IL3, IL4, IL5, IL6, and IL7 that are stacked. The first organic layer PL1 is further disposed on a top surface IL1T of the inorganic layer IL1. Based on this, the adhesion between the first organic layer PL1 and the inorganic layer IL1 is further utilized to increase the structural strength of the stretchable circuit substrate 1, thereby preventing the stretchable circuit substrate 1 from being fractured at the interface between the active region PX and the circuit region CR.

Referring also to FIG. 2, in this embodiment, the first island structure IS1 and the second island structure IS2 further include a contact window CW1 penetrating the inorganic layers IL1, IL2, and IL3. The first conductive layer ML1 is electrically connected to the driving structure DS1 of the first island structure IS1 through the contact window CW1 of the first island structure IS1, and is electrically connected to the driving structure DS2 of the second island structure IS2 through the contact window CW1 of the second island structure IS2.

In order to fully illustrate the various embodiments of the disclosure, other embodiments of the disclosure are described below. It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

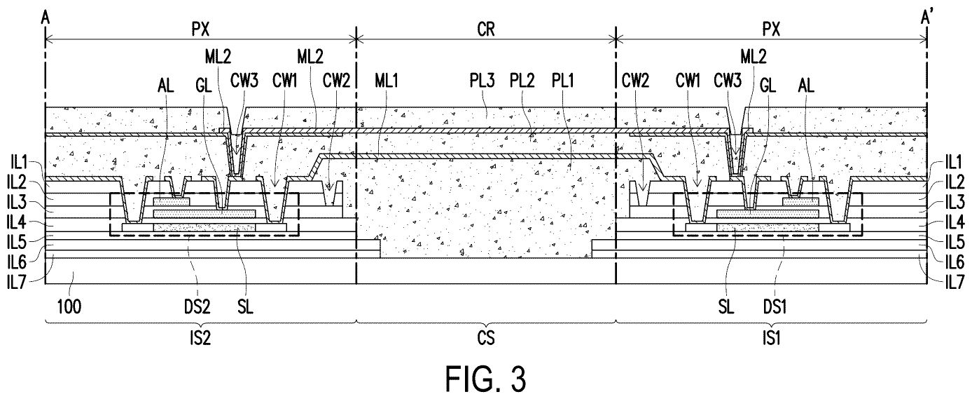

Referring to FIG. 3, FIG. 3 is a cross-sectional schematic diagram along a curve AA′ shown in FIG. 1 according to an embodiment of the disclosure.

The difference between the stretchable circuit substrate 1 of this embodiment and the stretchable circuit substrate 1 in FIG. 2 lies in that the circuit structure CS includes a first organic layer PL1, a second organic layer PL2, a third organic layer PL3, a first conductive layer ML1 and a second conductive layer ML2. The first organic layer PL1, the second organic layer PL2, and the third organic layer PL3 may include the same or similar materials. The first conductive layer ML1 and the second conductive layer ML2 may include the same or similar materials. The second conductive layer ML2 is disposed on the first organic layer PL1 and the second organic layer PL2.

The second organic layer PL2 is further disposed on the inorganic layers IL1, IL2, IL3, IL4, IL5, IL6, and IL7 of the first island structure IS1 and the second island structure IS2, and the first island structure IS1 and the second island structure IS2 further include a contact window CW3 penetrating the second organic layer PL2. The second conductive layer ML2 is electrically connected to the driving structure DS1 of the first island structure IS1 through the contact window CW3 of the first island structure IS1, and is electrically connected to the driving structure DS2 of the second island structure IS2 through the contact window CW3 of the second island structure IS2.

In some embodiments, the first conductive layer ML1 may be configured to transmit a data signal, and the second conductive layer ML2 may be connected to a gate driving circuit. The gate driving circuit may be a gate driver on array (GOA). In some embodiments, the gate driving circuit may be a gate driver on array on a single side of the stretchable circuit substrate 1, or a gate driver on array on multiple sides of the stretchable circuit substrate 1. In some embodiments, the stretchable circuit substrate 1 may be disposed in a spliced display. It should be noted that the stretchable circuit substrate 1 of the disclosure is not limited to the structure shown in FIG. 3. Any one of the first conductive layer ML1 and the second conductive layer ML2 may be electrically connected to any component of the driving structure of the island structure according to design requirements. For example, in some embodiments, when the first conductive layer ML1 serves to transmit a scan signal and is electrically connected to the gate driving circuit, the first conductive layer ML1 may be electrically connected to a gate GL via a through hole. In some other embodiments, the second conductive layer ML2 may be electrically connected to a conductive layer AL of the driving structure via a through hole. In addition, in some embodiments, in the circuit region CR, one or more other conductive layers may be disposed between the first conductive layer ML1 and the second conductive layer ML2.

The difference between the stretchable circuit substrate 1 of this embodiment and the stretchable circuit substrate 1 in FIG. 2 further lies in that the first island structure IS1 and the second island structure IS2 further include a contact window CW2 penetrating the inorganic layers IL1 and IL2, in which the inorganic layer IL3 is exposed by the contact window CW2. The first organic layer PL1 fills the contact windows CW2 of the first island structure IS1 and the second island structure IS2, and directly contacts the inorganic layers IL1, IL2, and IL3 in the contact windows CW2. Based on this, the adhesion between the first organic layer PL1 and the inorganic layers IL1, IL2 and IL3 in the contact window CW2 is further utilized to increase the structural strength of the stretchable circuit substrate 1, thereby preventing the stretchable circuit substrate 1 from being fractured at the interface between the active region PX and the circuit region CR.

In the multiple embodiments to be described later, the first island structure IS1 is taken as an example to illustrate the structure of each island structure in the stretchable circuit substrate 1.

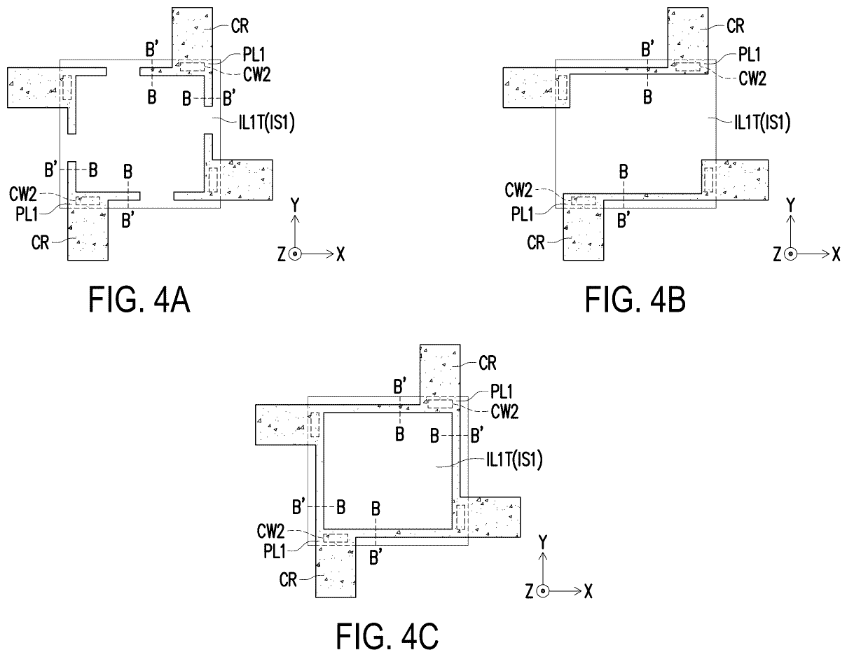

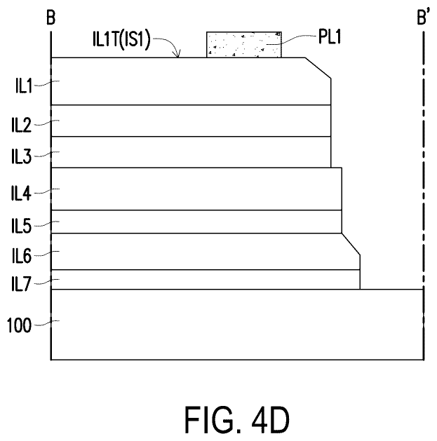

Refer to FIG. 1, FIG. 3, FIG. 4A and FIG. 4D simultaneously, FIG. 4A is a planar schematic diagram of the first island structure in FIG. 1 and FIG. 3 according to an embodiment of the disclosure, and FIG. 4D is a cross-sectional schematic diagram along each line segment BB′ shown in FIG. 4A.

In this embodiment, the first organic layer PL1 is also disposed on the top surface IL1T of the inorganic layer IL1. The first organic layer PL1 on the top surface IL1T extends along the X direction and the Y direction, and the first organic layer PL1 on the top surface IL1T is integrally formed with the first organic layer PL1 on a corresponding circuit region CR. Based on this, the contact area between the first organic layer PL1 and the inorganic layer IL1 is increased, thereby further utilizing the adhesion between the first organic layer PL1 and the inorganic layer IL1 to increase the structural strength of the stretchable circuit substrate 1, preventing the stretchable circuit substrate 1 from being fractured at the interface between the active region PX and the circuit region CR.

Refer to FIG. 1, FIG. 3, FIG. 4B and FIG. 4D simultaneously, FIG. 4B is a planar schematic diagram of the first island structure in FIG. 1 and FIG. 3 according to an embodiment of the disclosure, and FIG. 4D is a cross-sectional schematic diagram along each line segment BB′ shown in FIG. 4B.

In this embodiment, the first organic layer PL1 is further disposed on the top surface IL1T of the inorganic layer IL1. The first organic layer PL1 on the top surface IL1T extends along the X direction, and the first organic layer PL1 on the top surface IL1T is integrally formed with the first organic layer PL1 on the corresponding two circuit regions CR. The two circuit regions CR are respectively located between the first island structure IS1 and two different island structures. Based on this, the adhesion between the first organic layer PL1 and the inorganic layer IL1 is further utilized to increase the structural strength of the stretchable circuit substrate 1, thereby preventing the stretchable circuit substrate 1 from being fractured at the interface between the active region PX and the circuit region CR.

Refer to FIG. 1, FIG. 3, FIG. 4C and FIG. 4D simultaneously, FIG. 4C is a planar schematic diagram of the first island structure in FIG. 1 and FIG. 3 according to an embodiment of the disclosure, and FIG. 4D is a cross-sectional schematic diagram along each line segment BB′ shown in FIG. 4C.

In this embodiment, the first organic layer PL1 is further disposed on the top surface IL1T of the inorganic layer IL1. The first organic layer PL1 on the top surface IL1T extends along the X direction and the Y direction to form a closed ring structure, and the first organic layer PL1 on the top surface IL1T is integrally formed with the first organic layer PL1 on the corresponding four circuit regions CR. The four circuit regions CR are respectively located between the first island structure IS1 and four different island structures. Based on this, the closed ring structure on the top surface IL1T and the collaboration of the first organic layer PL1 on the four circuit regions CR are used to increase the structural strength of the stretchable circuit substrate 1, thereby preventing the stretchable circuit substrate 1 from being fractured at the interface between the active region PX and the circuit region CR.

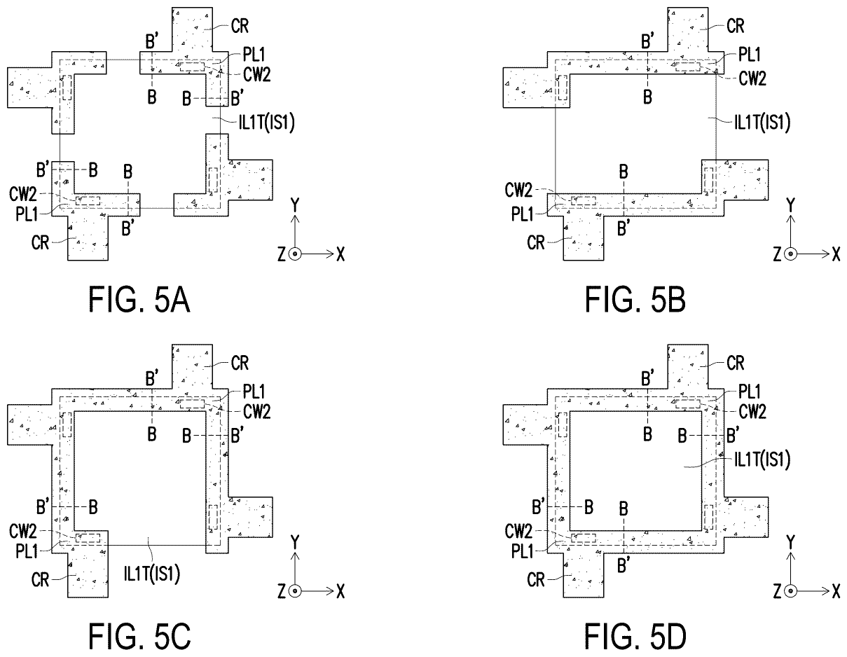

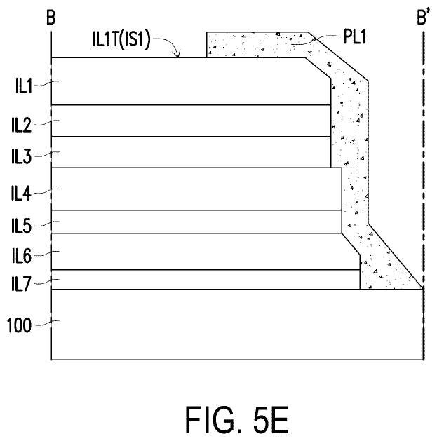

Refer to FIG. 1, FIG. 3, FIG. 5A and FIG. 5E simultaneously, FIG. 5A is a planar schematic diagram of the first island structure in FIG. 1 and FIG. 3 according to an embodiment of the disclosure, and FIG. 5E is a cross-sectional schematic diagram along each line segment BB′ shown in FIG. 5A.

In this embodiment, the first organic layer PL1 is further disposed on the top surface IL1T of the inorganic layer IL1 and on the side surfaces of the inorganic layers IL1, IL2, IL3, IL4, IL5, IL6, and IL7, and extends along the X direction and the Y direction. The first organic layer PL1 on the top surface IL1T and on the side surfaces of the inorganic layers IL1, IL2, IL3, IL4, IL5, IL6, and IL7 is integrally formed with the first organic layer PL1 on a corresponding circuit region CR. As shown in FIG. 5A and FIG. 5E, the side surfaces of the inorganic layers IL1, IL2, IL3, IL4, IL5, IL6, and IL7 include multiple side surfaces respectively facing the +X direction, the −X direction, the +Y direction, and the −Y direction. Based on this, the contact area between the first organic layer PL1 and the inorganic layers IL1, IL2, IL3, IL4, IL5, IL6, and IL7 is increased, thereby further utilizing the adhesion between the first organic layer PL1 and the inorganic layers IL1, IL2, IL3, IL4, IL5, IL6, and IL7 to increase the structural strength of the stretchable circuit substrate 1, preventing the stretchable circuit substrate 1 from being fractured at the interface between the active region PX and the circuit region CR.

Refer to FIG. 1, FIG. 3, FIG. 5B and FIG. 5E simultaneously, FIG. 5B is a planar schematic diagram of the first island structure in FIG. 1 and FIG. 3 according to an embodiment of the disclosure, and FIG. 5E is a cross-sectional schematic diagram along each line segment BB′ shown in FIG. 5B.

In this embodiment, the first organic layer PL1 is further disposed on the top surface IL1T of the inorganic layer IL1 and on the side surfaces of the inorganic layers IL1, IL2, IL3, IL4, IL5, IL6, and IL7, and extends along the X direction. The first organic layer PL1 on the top surface IL1T and on the side surfaces of the inorganic layers IL1, IL2, IL3, IL4, IL5, IL6, and IL7 is integrally formed with the first organic layer PL1 on the corresponding two circuit regions CR. The two circuit regions CR are respectively located between the first island structure IS1 and two different island structures. As shown in FIG. 5B and FIG. 5E, the side surfaces of the inorganic layers IL1, IL2, IL3, IL4, IL5, IL6, and IL7 include multiple side surfaces respectively facing the +Y direction and the −Y direction. Based on this, the adhesion between the first organic layer PL1 and the inorganic layers IL1, IL2, IL3, IL4, IL5, IL6, and IL7 is further utilized to increase the structural strength of the stretchable circuit substrate 1, thereby preventing the stretchable circuit substrate 1 from being fractured at the interface between the active region PX and the circuit region CR.

Refer to FIG. 1, FIG. 3, FIG. 5C and FIG. 5E simultaneously, FIG. 5C is a planar schematic diagram of the first island structure in FIG. 1 and FIG. 3 according to an embodiment of the disclosure, and FIG. 5E is a cross-sectional schematic diagram along each line segment BB′ shown in FIG. 5C.

In this embodiment, the first organic layer PL1 is further disposed on the top surface IL1T of the inorganic layer IL1 and on the side surfaces of the inorganic layers IL1, IL2, IL3, IL4, IL5, IL6, and IL7, and extends along the X direction and the Y direction. The first organic layer PL1 on the top surface IL1T and on the side surfaces of the inorganic layers IL1, IL2, IL3, IL4, IL5, IL6, and IL7 is integrally formed with the first organic layer PL1 on the corresponding four circuit regions CR. The four circuit regions CR are respectively located between the first island structure IS1 and four different island structures. As shown in FIG. 5C and FIG. 5E, the side surfaces of the inorganic layers IL1, IL2, IL3, IL4, IL5, IL6, and IL7 include multiple side surfaces respectively facing the +Y direction, the +X direction, and the −X direction. Based on this, the adhesion between the first organic layer PL1 and the inorganic layers IL1, IL2, IL3, IL4, IL5, IL6, and IL7 and the collaboration of the first organic layer PL1 on the four circuit regions CR are further utilized to increase the structural strength of the stretchable circuit substrate 1, thereby preventing the stretchable circuit substrate 1 from being fractured at the interface between the active region PX and the circuit region CR.

Refer to FIG. 1, FIG. 3, FIG. 5D and FIG. 5E simultaneously, FIG. 5D is a planar schematic diagram of the first island structure in FIG. 1 and FIG. 3 according to an embodiment of the disclosure, and FIG. 5E is a cross-sectional schematic diagram along each line segment BB′ shown in FIG. 5D.

In this embodiment, the first organic layer PL1 is further disposed on the top surface IL1T of the inorganic layer IL1 and on the side surfaces of the inorganic layers IL1, IL2, IL3, IL4, IL5, IL6, and IL7, and extends along the X direction and the Y direction. The first organic layer PL1 on the top surface IL1T and on the side surfaces of the inorganic layers IL1, IL2, IL3, IL4, IL5, IL6, and IL7 forms a closed ring structure, and is integrally formed with the first organic layer PL1 on the corresponding four circuit regions CR. The four circuit regions CR are respectively located between the first island structure IS1 and four different island structures. The closed ring structure is a three-dimensional structure. As shown in FIG. 5D and FIG. 5E, the side surfaces of the inorganic layers IL1, IL2, IL3, IL4, IL5, IL6, and IL7 include multiple side surfaces respectively facing the +X direction, the −X direction, the +Y direction, and the −Y direction. Based on this, the three-dimensional closed ring structure on the top surface IL1T and the collaboration of the first organic layer PL1 on the four circuit regions CR are further used to increase the structural strength of the stretchable circuit substrate 1, thereby preventing the stretchable circuit substrate 1 from being fractured at the interface between the active region PX and the circuit region CR.

To sum up, the stretchable circuit substrate provided by the embodiment of the disclosure is configured with an organic layer on the circuit region between different island structures, and the corresponding island structures are connected by the organic layer, which effectively enhances the maximum stretchability ratio of the stretchable circuit substrate and prevents fractures from readily occurring at the interface between its active region and circuit region. The organic layer may also be disposed in the island structure to improve its overall structural strength and further enhance the reliability of the stretchable circuit substrate.

What is claimed is:

1. A stretchable display device, having a plurality of active regions and a plurality of circuit regions, wherein the circuit regions are respectively located between the active regions, the stretchable circuit substrate comprises:
a plurality of island structures, respectively disposed on the active regions, wherein the island structures comprise a first island structure and a second island structure, and each of the island structures comprises a driving structure;
a first organic layer, at least disposed on the circuit region between the first island structure and the second island structure, and connected to the first island structure and the second island structure; and
a first conductive layer, disposed on the first organic layer, and electrically connected to the driving structure of the first island structure and the driving structure of the second island structure.

2. The stretchable display device according to claim 1, wherein the first island structure further comprises at least one inorganic layer and a first contact window, wherein the first contact window penetrates the at least one inorganic layer, and the first conductive layer is connected to the driving structure of the first island structure through the first contact window.

3. The stretchable display device according to claim 2, wherein the first island structure further comprises a second contact window, wherein the second contact window penetrates the at least one inorganic layer, and the first organic layer fills the second contact window.

4. The stretchable display device according to claim 1, wherein the first island structure further comprises at least one inorganic layer, the first organic layer is further disposed on a top surface of the at least one inorganic layer.

5. The stretchable display device according to claim 4, wherein the first organic layer forms a closed ring structure on the top surface of the at least one inorganic layer.

6. The stretchable display device according to claim 4, wherein the first organic layer is further disposed on at least one side surface of the at least one inorganic layer.

7. The stretchable display device according to claim 6, wherein the at least one side surface comprises a plurality of side surfaces, and the first organic layer forms a closed ring structure on the side surfaces of the at least one inorganic layer.

8. The stretchable display device according to claim 6, wherein the at least one side surface comprises a plurality of side surfaces, and the first organic layer comprises a three-dimensional closed ring structure.

9. The stretchable display device according to claim 4, wherein the first organic layer is further disposed on the circuit region between the first island structure and a third island structure, and the first organic layer is integrally formed.

10. The stretchable display device according to claim 1, further comprising a second conductive layer disposed on the first organic layer and electrically connected to the driving structure of the first island structure and the driving structure of the second island structure.

11. The stretchable display device according to claim 10, wherein the second conductive layer is connected to a gate driver on array.

12. A stretchable display device, having a plurality of active regions and a plurality of circuit regions, wherein the circuit regions are respectively located between the active regions, the stretchable circuit substrate comprises:
a plurality of island structures, respectively disposed on the active regions, wherein the island structures comprise a first island structure and a second island structure, and each of the island structures comprises a driving structure;
a first organic layer, at least disposed on the circuit region between the first island structure and the second island structure, and connected to the first island structure and the second island structure; and
a first conductive layer, disposed on the first organic layer, and electrically connected to the driving structure of the first island structure and the driving structure of the second island structure,
wherein the first island structure further comprises at least one inorganic layer, the first organic layer is further disposed on a top surface of the at least one inorganic layer,
wherein the first organic layer is further disposed on at least one side surface of the at least one inorganic layer,
wherein the first organic layer is further disposed on the circuit region between the first island structure and a third island structure, and the first organic layer is integrally formed.

13. The stretchable display device according to claim 12, wherein the at least one side surface comprises a plurality of side surfaces, and the first organic layer forms a closed ring structure on the side surfaces of the at least one inorganic layer.

14. The stretchable display device according to claim 12, wherein the at least one side surface comprises a plurality of side surfaces, and the first organic layer comprises a three-dimensional closed ring structure.

15. The stretchable display device according to claim 12, wherein the first island structure further comprises a first contact window, wherein the first contact window penetrates the at least one inorganic layer, and the first conductive layer is connected to the driving structure of the first island structure through the first contact window.
